(19) United States
(12) Patent Application Publication
(10) Pub. No.: US 2009/0072851 A1
(43) Pub. Date: Mar. 19, 2009

(54) Multi-Pivot Probe Card For Testing Semiconductor Devices

(75) Inventors: Lakshmikanth Namburi, Duarte, CA (US); Salleh Ismail, El Monte, CA (US)

Correspondence Address: MANUEL F. DE LA CERRA, 6885 CATAMARAN DRIVE, CARLSBAD, CA, 92011, US

(73) Assignee: TOUCHDOWN TECHNOLOGIES, INC., Baldwin Park, CA (US)

(21) Appl. No.: 12/208,223

(22) Filed: Sep. 10, 2008

Related U.S. Application Data
(63) Continuation-in-part of application No. 11/855,094, filed on Sep. 13, 2007.

(51) Int. Cl. G01R 1/067

(52) U.S. Cl. 324/762

(57) ABSTRACT

A novel probe design is presented that comprises a plurality of pivots. These pivots allow the probe to store the displacement energy more efficiently. The novel probe comprises a substrate, and a probe connected to the substrate. The probe further comprises a base that is connected to the substrate, a bending element connected to the base and a probe tip connected to the bending element. In one embodiment, the plurality of pivots may be connected to the substrate such that a portion of the probe may contact the plurality of pivots while the probe tip contacts the device. In another embodiment, the plurality of pivots is connected to the bending element, such that the plurality of pivots may contact the substrate while the probe tip contacts the device. The bending element may also comprise a forked bending element connected to the base, such as the forked bending structure described in co-pending and related patent application Ser. No. 11/855,094. The forked bending structure may include at least a first prong connected to a second prong through a prong connecting structure and a handle connected to the prong connecting structure.

### 1. FIELD OF THE INVENTION

The present invention relates to devices for testing semiconductor devices and more particularly to the design of probe contactors for such testing.

### 2. BACKGROUND OF THE INVENTION

Integrated circuits are made in a bulk parallel process by patterning and processing semiconductor wafers. Each wafer contains many identical copies of the same integrated circuit referred to as a “die.” It may be preferable to test the semiconductor wafers before the die is cut into individual integrated circuits and packaged for sale. If defects are detected the defective die can be culled before wasting resources packaging a defective part. The individual die can also be tested after they have been cut into individual integrated circuits and packaged.

To test a wafer or an individual die—commonly called the device under test or DUT—a probe card is commonly used which comes into contact with the surface of the DUT. The probe card generally contains three unique characteristics: (1) an XY array of individual probes that move in the Z direction to allow contact with the die pad; (2) an electrical interface to connect the card to a circuit test apparatus; and (3) a rigid reference plane defined in such a way that the probe card can be accurately mounted in the proper location. When the probe card is brought in contact with the die pad, the Z-direction movement allows for a solid contact with the probe tip. The probe card ultimately provides an electrical interface that allows a circuit test apparatus to be temporarily connected to the DUT. This method of die testing is extremely efficient because many die can be tested at the same time. To drive this efficiency even higher, probe card manufactures are making larger probe cards with an ever-increasing numbers of probes.

A commonly used probe design used to test a semiconductor die is a cantilever probe. FIGS. 4A and 4B illustrate a conventional cantilever probe. The probe (405) comprises a probe tip (410), a probe post (412), a bending element (415), and a probe base (420), which is mounted to a substrate (425). This entire structure is referred to herein as the probe card. The entire probe card is generally moved in the Z-direction (depicted by arrow 440) causing the bending element (415) to bend allowing the probe tip (410) to come into contact with the die pad that is under test. FIG. 4B illustrates how the probe bending element (435) bends while being brought into contact with the die. As an individual probe travels to make contact with the DUT contact pad (this event is called a touchdown), the probe tip scrubs the contact pad, which perfects an electrical contact with the die such that testing can commence. The die contact pads, which are typically aluminum, have a native oxide layer, and the probe tip must cut through the oxide layer to perfect the electrical connection. Once testing is complete, the probe (405) is moved away from the die pad and the probe springs back to its original position.

The cantilever design, however, has a shortcoming—i.e., the inefficient distribution of stresses. During touchdown, a cantilever probe bends, which creates stresses on the probe that appear concentrated at the top and bottom surfaces of the bending element near the probe base end of the probe. FIG. 5A illustrates a length-wise cross-sectional view of the stresses experienced by the bending element of a cantilever probe, while FIG. 5B illustrates the width-wise cross-sectional views (Sections A-A and B-B) of the stresses at each end of the element. The left side of the figure, near Section A-A, (indicated by part 505) is the part of the bending element that is near the probe base, with the right side, near Section B-B, (part 510) near the probe tip. The area of the bending element that experiences stresses which are greater than 50% of the maximum stress is shown hatched (515). The corresponding volume of the bending bar that experiences greater than 50% of maximum stress is about 25% of the total cantilever bar volume, and that volume is localized near the probe base (405). The opposite side of the bending bar (510) experiences very low stress. It is clear from FIGS. 5A and 5B that the stress distribution is inefficient because only small portions of the bending element absorb the stress. And it is in these small portions where the probe is more likely to fail forcing manufacturers to redesign their cantilever probes.

For example, U.S. Pat. No. 6,255,126, (FIG. 28B from that patent is shown in FIG. 6 hereto) discloses a probe design with a wider bending element near the probe base (location 605)—i.e., the location of the highest stress. A wider bending element near the probe base, however, adversely affects the packing density of the probe card.

Another cantilever probe design for more efficient distribution of stress is a leaf spring design. Referring to FIGS. 7A-7C, the leaf spring probe card 705 contains a substrate 710, a base 715, a plurality of bending elements (720, 725, 730) and a probe tip 735. The entire probe card is generally moved in the Z-direction (depicted by arrow 740) causing the plurality of bending element to bend allowing the probe tip (735) to come into contact with the die pad that is under test. FIG. 7B illustrates how the first of the probe bending element (730) bends while being brought into contact with the die. The entire displacement energy is stored by the first bending element (730) and the stresses are located near location 745. As the probe card 705 is brought closer to the die pad that is under test, the second bending element (725) begins to absorb the displacement energy—see FIG. 7C. At this point, the stresses are also distributed at location 750. Once the third probe bending element (720) begins to absorb displacement energy, the stresses are also distributed at location 755. This design, therefore, allows stresses to be distributed over several parts of the probe design. This design, however, is very complicated to construct, which results in a low yield efficiency when manufacturing probe cards.

What is needed, therefore, is a cantilever probe with more evenly distributed stress, that does not have the associated shortcomings of the prior art.

### 3. SUMMARY OF THE INVENTION

The present disclosure provides a novel probe design that comprises a plurality of pivots. These pivots allow the probe to store the displacement energy more efficiently. The novel probe comprises a substrate, and a probe connected to the substrate. The probe further comprises a base that is connected to the substrate, a bending element connected to the base and a probe tip connected to the bending element. In one embodiment, the plurality of pivots may be connected to the substrate such that a portion of the probe may contact the plurality of pivots while the probe tip contacts the device. In another embodiment, the plurality of pivots is connected to the bending element, such that the plurality of pivots may contact the substrate while the probe tip contacts the device.

In yet another embodiment, the bending element may comprise a forked bending element connected to the base, such as the forked bending structure described in co-pending and related patent application Ser. No. 11/855,094. The forked bending structure may include at least a first prong connected to a second prong through a prong connecting structure and a handle connected to the prong connecting structure.

The probe card may be manufactured using Microelectromechanical systems (MEMS) Technology including photolithography. It also may be manufactured using two photolithographic layers, wherein the bending element is manufactured using a first photolithographic layer comprised of a first material, and the plurality of pivots is manufactured using a second photolithographic layer comprised of a second material. The first material may have a different Young's Modulus than the second material. The bending element may be comprised of a nickel alloy. In yet another embodiment, the probe includes a probe post connected to the probe tip. The surface of the probe post is manufactured such that the probe post can be optically distinguished from the probe tip.

### 4. BRIEF DESCRIPTION OF THE DRAWINGS

FIGS. 1A-1C illustrate an embodiment of a novel probe design with a plurality of pivots.

FIGS. 2A-2C illustrate an embodiment of a novel probe design with a plurality of pivots.

FIGS. 3A-3D illustrate an embodiment of a novel probe design with a plurality of pivots, using the forked probe design disclosed in co-pending and related patent application Ser. No. 11/855,094.

FIGS. 4A and 4B illustrate a cantilever probe.

FIGS. 5A and 5B are a length-wise cross-section and width-wise cross-sections, respectively, of the stresses experienced by the bending element of a cantilever probe.

FIG. 6 illustrates a probe bending element that is wider at the base.

FIGS. 7A-7C illustrate a leaf spring embodiment of a cantilever probe.

### 5. DETAILED DESCRIPTION OF THE PREFERRED EMBODIMENTS

What is described below is a novel probe design that comprises a multi-pivot bending element. The multi-pivots allow the novel probe to store the displacement energy at several positions across the bending element. The multi-pivot design is not complicated to construct and allows for greater packing density and less probe failure from material fatigue.

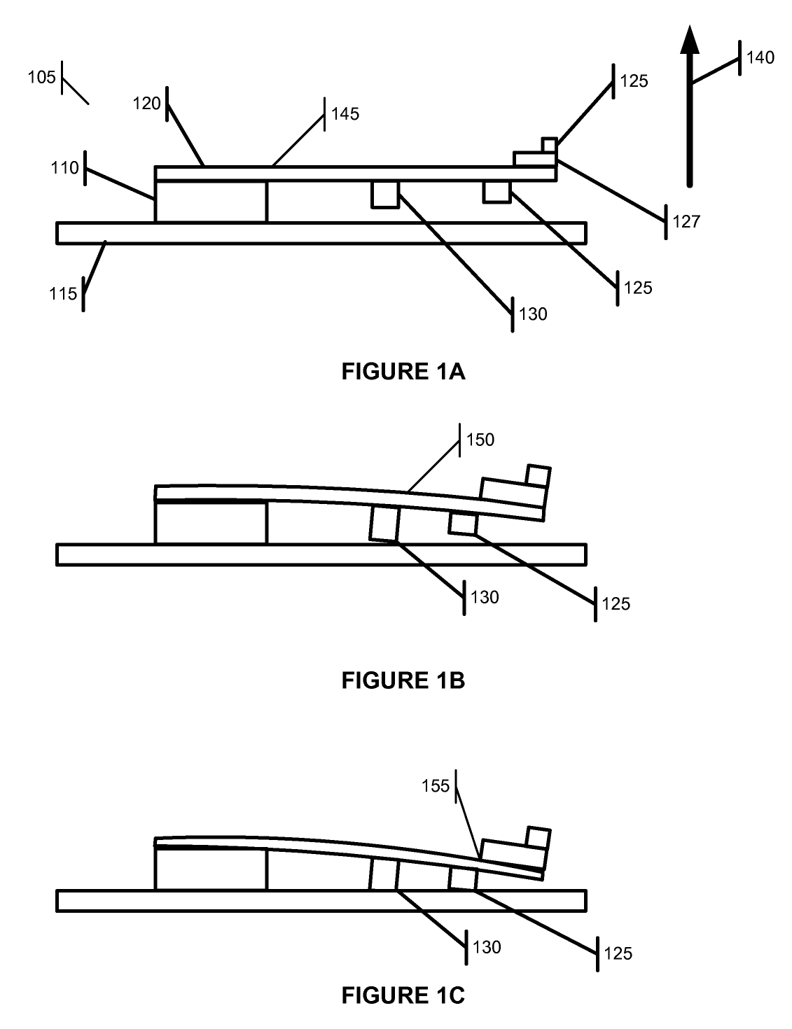

FIGS. 1A-1C present an embodiment of a novel multi-pivot probe card (105). The probe card (105) comprises a probe base (110) connected to the substrate (115), a bending element (120), a probe post (127) and a probe tip (125). Connected to the probe bending element (120) are a plurality of pivots (125, 130). The entire probe card (105) is generally moved in the Z-direction (depicted by arrow 140) causing the bending element (120) to bend allowing the probe tip (225) to come into contact with the die pad that is under test. Initially, all of the displacement energy stresses are located at location 145, near the probe base 110. FIG. 1B illustrates how the probe bending element (120) bends while being brought into contact with the die. Once the bending element (120) bends sufficiently, pivot (130) comes into contact with the substrate (115). At this point, displacement energy stresses are also distributed at location 150. As the probe card 105 is driven closer to the die pad that is under test, the bending element (120) continues to bend, causing the second pivot (125) to contact the substrate (115), as shown in FIG. 1C. At this point, displacement energy stresses are also distributed at location 155. Therefore, the displacement energy stresses are more evenly distributed across more of the bending element. This design reduces material fatigue failure. And because the displacement energy stresses are no longer localized near the probe base, the probe base can have a smaller foot print, promoting higher probe packing densities.

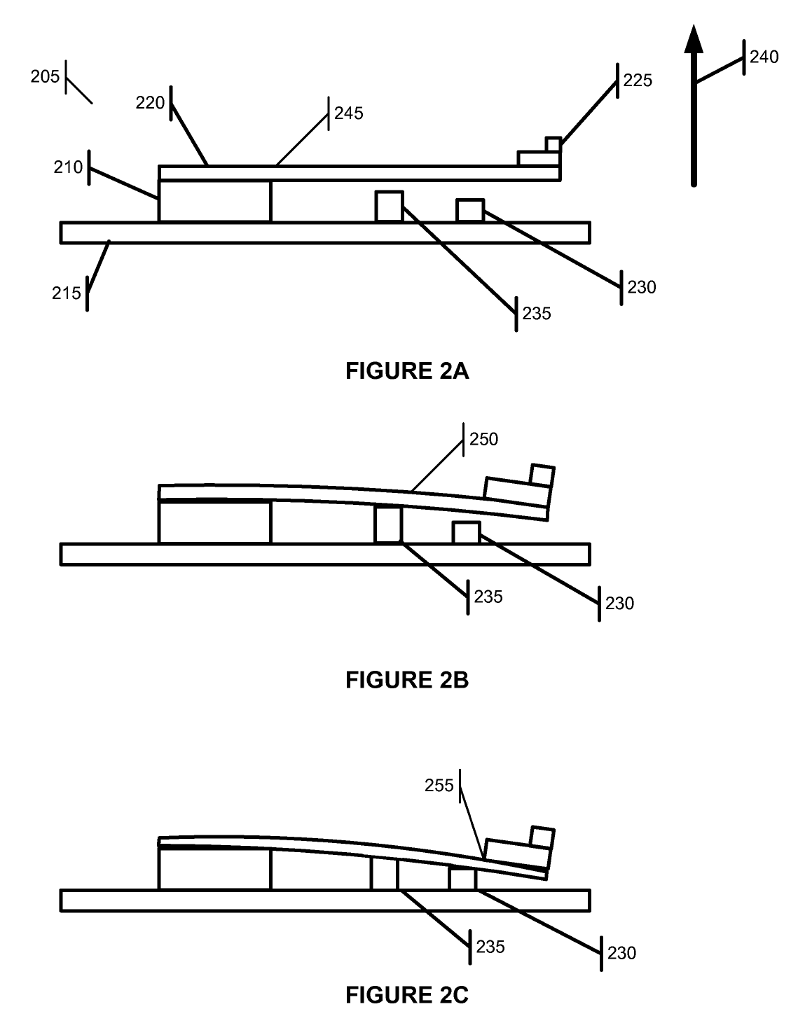

FIGS. 2A-2C present yet another embodiment of a novel multi-pivot probe card (205). The probe card (205) comprises a probe base (210) connected to the substrate (215), a bending element (220) and a probe tip (225). Connected to the substrate (215) are a plurality of pivots (230, 235). The entire probe card (205) is generally moved in the Z-direction (depicted by arrow 240) causing the bending element (220) to bend allowing the probe tip (225) to come into contact with the die pad that is under test. Initially, all of the displacement energy stresses are located at location 245, near the probe base 210. FIG. 2B illustrates how the probe bending element (220) bends while being brought into contact with the die. Once the bending element (220) bends sufficiently it comes into contact with pivot (235). At this point, displacement energy stresses are also distributed at location 250. As the probe card 205 is driven closer to the die pad that is under test, the bending element (220) continues to bend, causing the bending element (220) to contact the second pivot (230), as shown in FIG. 2C. At this point, displacement energy stresses are also distributed at location 255. Again, the displacement energy stresses are more evenly distributed across more of the bending element, leading to reduced material fatigue failure. And this probe card design promotes higher probe packing densities.

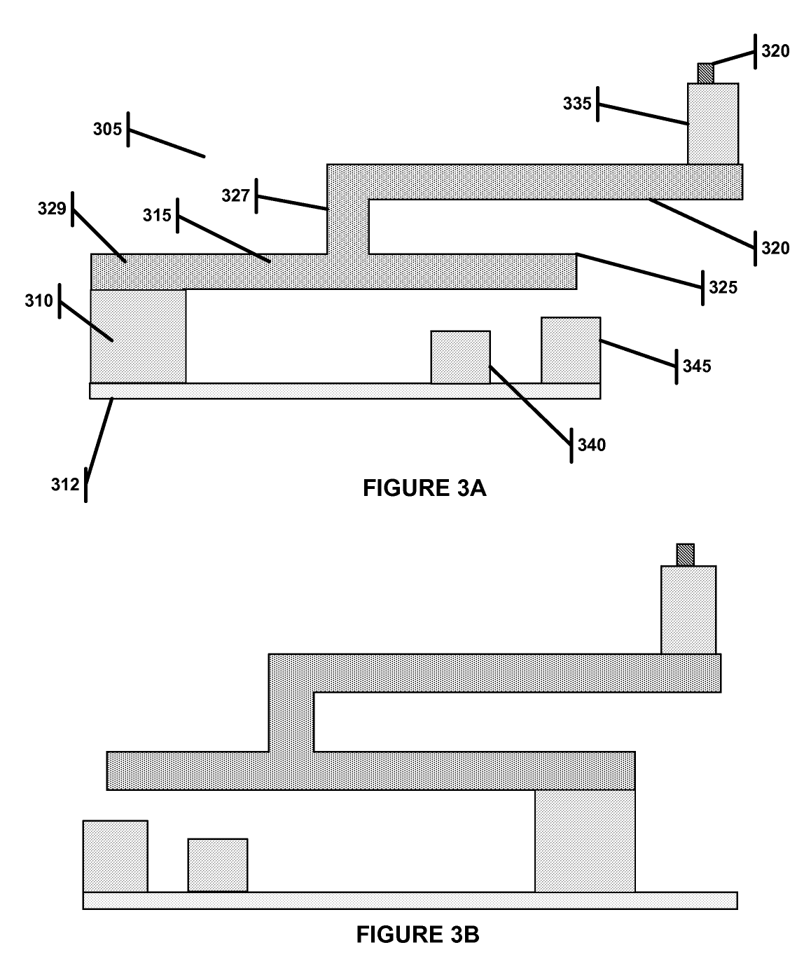

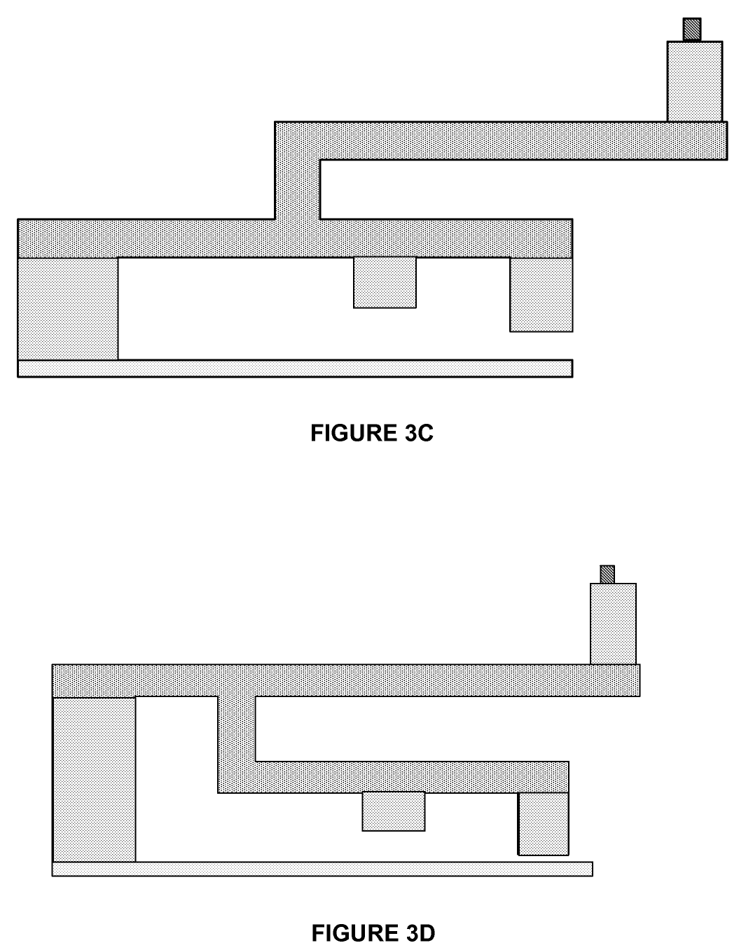

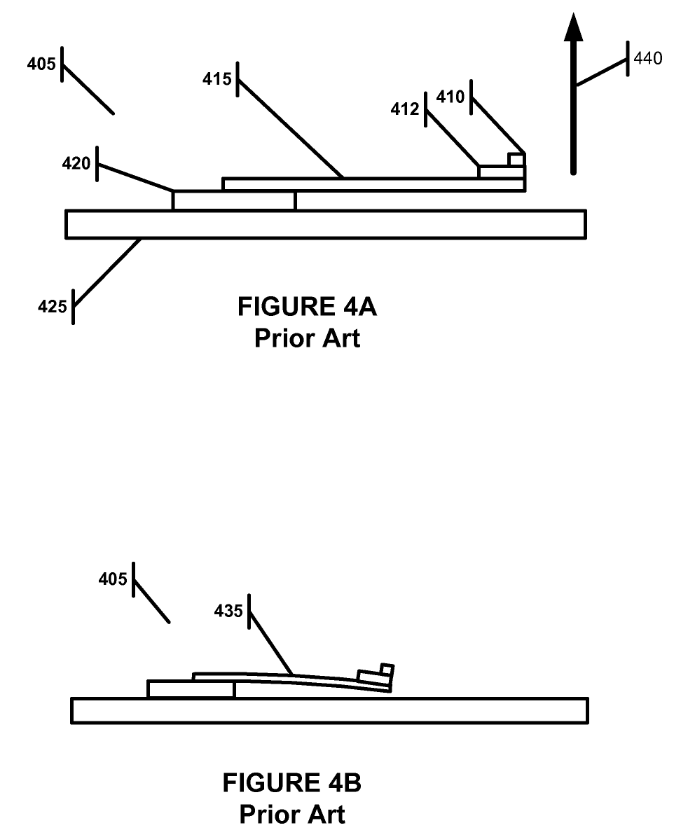

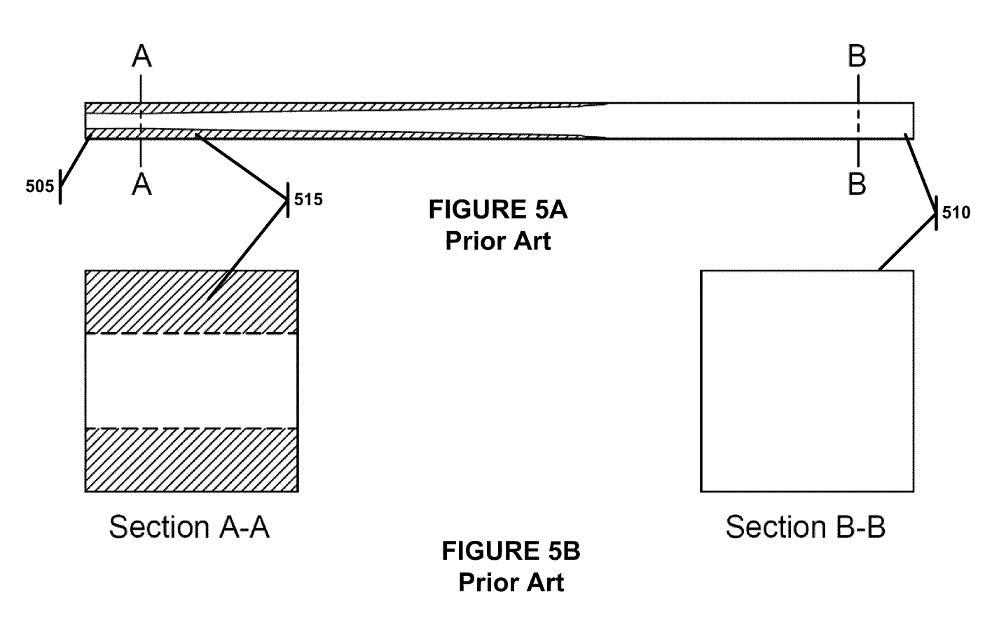

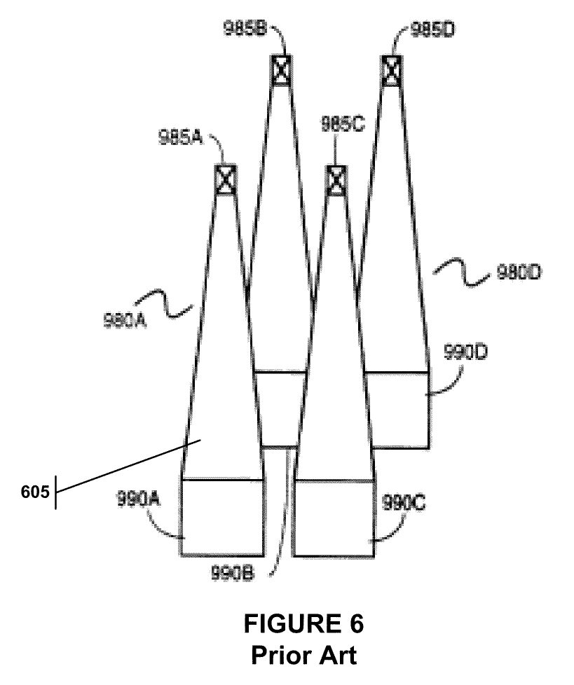

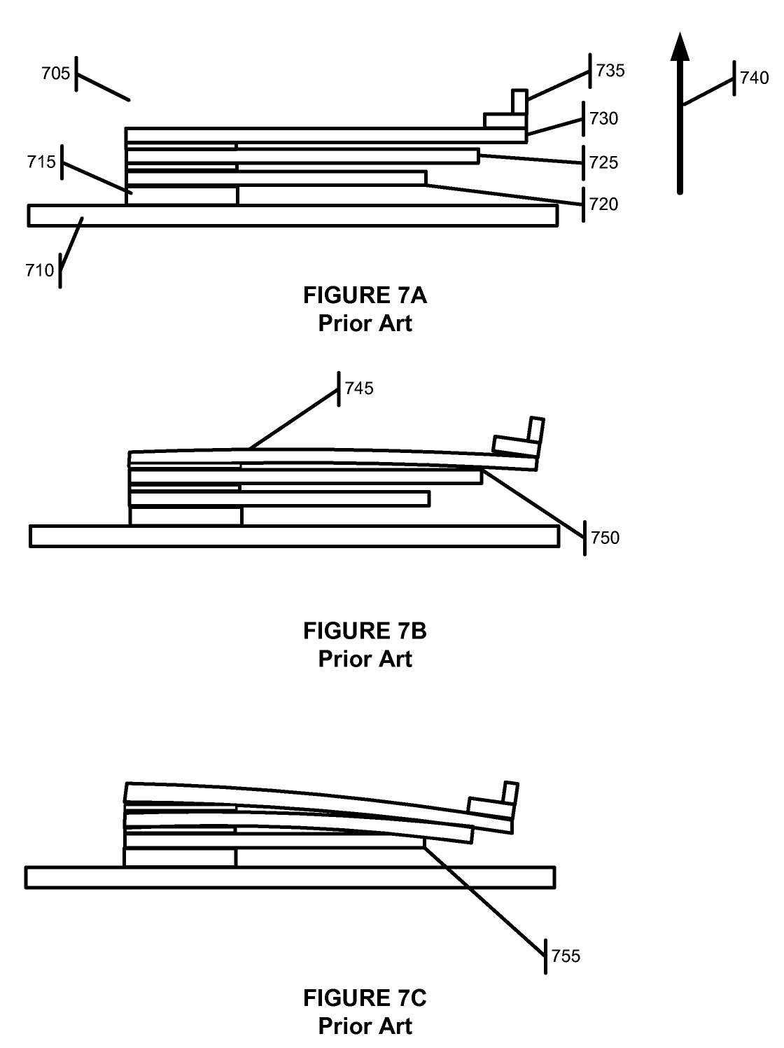

The multi-pivot design may also be used in conjunction with the co-pending U.S. patent application Ser. No. 11/855,094 entitled “A Forked Probe For Testing Semiconductor Devices” by Salleh Ismail (a co-inventor of the present application), assigned to the same assignee of the present application. The content of the co-pending patent application is incorporated herein by reference in its entirety. FIGS. 3A-3D illustrate several embodiments using multi-pivots with a forked probe design. Referring to FIG. 3A, presents an embodiment of a novel forked probe (305) of co-pending related application Ser. No. 11/855,094. The forked probe (105) comprises a probe base (310) connected to the substrate (312) and a forked bending element (315) (shaded for illustration purposes). The forked bending element (315) can best be visualized as a table fork that includes at least two prongs (320) and (325), a prong connecting structure (327) between the prongs and a handle (329) that connects to the probe base (310) and the prong connecting structure (327). A probe tip (330) is connected to a first prong (320) through a probe post (335). Connected to the substrate are pivots (340 and 345) which are placed at a distance from the second prong (325). As the probe 305 makes contact with the DUT, the forked bending element (315) will make contact with pivot (345). As the forked bending element continues to bend, storing more displacement energy, it will also contact pivot (340). By introducing the two pivots, the displacement energy stresses are distributed over more of the forked bending element. Similarly in FIGS. 3B-3D, the two pivot design allows the forked probe to more efficiently distribute stress. As mentioned before, by using more of the bending element to absorb the stresses, less material is needed and higher probe packing densities are possible.

While each of the disclosed embodiments contains only two pivots, more pivots may be used to further refine the design. Using, for example, three pivots in embodiment illustrated in FIG. 1, would result in potentially four areas along the bending element where the displacement stresses could concentrate (as opposed to the three areas illustrated in FIG. 1—i.e., location 145, 150, 155).

The novel probe cards described herein may be constructed using several techniques, including those described in U.S. patent application Ser. Nos. 11/019,912 and 11/102,982, both commonly owned by the present applicant and hereby also incorporated by reference. Those two applications describe the use of general photolithographic pattern-plating techniques combined with the use of sacrificial metals to further create microstructures such as probes. The probes may be manufactured using several types of materials. The most common of which are nickel alloys that are high performance and preferably plateable. Such alloys may include NiCo and NiMn.

U.S. patent application Ser. No. 11/194,801 teaches forming different parts of the probe during different layers of photolithography, a feature made possible using the photolithography process described in U.S. application Ser. Nos. 11/019,912 and 11/102,982. Using this technique, it is possible to manufacture the various parts of the probe with different materials, which allow for further fine tuning of the multi-pivot probe characteristics. For example, to obtain probe with a bending element that is more plastically deformable, the bending element may be formed of one alloy. In certain designs, it may not be advantageous to have a pliable or deformable pivot, thus the pivots may be constructed of an alternative alloy.

U.S. patent application Ser. No. 11/194,801 also teaches a novel probe tip to ensure that the machine vision systems can optically differentiate the probe tip from the probe post. For example, the probe post can be manufactured with a roughened surface. The surface may be roughened prior to lithographically pattern-plating the probe tip on the probe post, so the probe tip is plated directly on the roughened surface. The roughened surface can be formed by plating metals and alloys such as Ni, Ni alloys such as NiMn, NiCo, NiW, or NiFe, W alloys such as CoW, Cr or similar metals at a high current, or by the addition of grain refiners or other additives such as Mn salt in a Ni Sulfamate bath, or in any other manner known in the art of electroplating and electroforming to create a roughened surface. Ultimately, light that is reflected back from the roughened surface is diffused and scattered. This helps the automatic vision systems to resolve the probe tip more clearly by providing greatly improved contrast between the probe tip and the probe post surface(s).

While the description above refers to particular embodiments of the present invention, it should be readily apparent to people of ordinary skill in the art that a number of modifications may be made without departing from the spirit thereof. The accompanying claims are intended to cover such modifications as would fall within the true spirit and scope of the invention. The presently disclosed embodiments are, therefore, to be considered in all respects as illustrative and not restrictive, the scope of the invention being indicated by the appended claims rather than the foregoing description. All changes that come within the meaning of and range of equivalency of the claims are intended to be embraced therein. Moreover, the applicants expressly do not intend that the following claims “and the embodiments in the specification to be strictly coextensive.” Phillips v. AHW Corp., 415 F.3d 1303, 1323 (Fed. Cir. 2005) (en banc).

1. A probe card for testing a semiconductor device, comprising:
a substrate;
a probe connected to the substrate, the probe comprising a base that is connected to the substrate, a bending element connected to the base and a probe tip connected to the bending element; and
wherein the probe elastically stores displacement energy while the probe tip contacts the device; and
a plurality of pivots connected to the substrate, wherein a portion of the probe may contact the plurality of pivots while the probe tip contacts the device.

2. The probe card of claim 1, wherein the bending element comprises a forked bending element connected to the base, wherein the forked bending element comprises:
at least a first prong connected to a second prong through a prong connecting structure; and
a handle connected to the prong connecting structure.

3. The probe card of claim 1 wherein the bending element is manufactured using lithography.

4. The probe card of claim 1 wherein the bending element is manufactured using a first photolithographic layer comprising a first material, and the plurality of pivots is manufactured using a second photolithographic layer comprising a second material.

5. The probe card of claim 4 wherein the first material has a different Young's Modulus than the second material.

6. The probe card of claim 1, wherein the bending element is comprised of a nickel alloy.

7. The probe card of claim 1 wherein the probe further comprises a probe post connected to the probe tip, wherein the surface of the probe post is manufactured such that the probe post can be optically distinguished from the probe tip.

8. A probe card for testing a semiconductor device, comprising:
a substrate;
a probe connected to the substrate, the probe comprising a base that is connected to the substrate, a bending element connected to the base and a probe tip connected to the bending element; and
wherein the probe elastically stores displacement energy while the probe tip contacts the device; and
a plurality of pivots connected to the bending element, wherein the plurality of pivots may contact the substrate while the probe tip contacts the device.

9. The probe card of claim 8, wherein the bending element comprises a forked bending element connected to the base, wherein the forked bending element comprises:
at least a first prong connected to a second prong through a prong connecting structure; and
a handle connected to the prong connecting structure.

10. The probe card of claim 8 wherein the bending element is manufactured using lithography.

11. The probe card of claim 8 wherein the bending element is manufactured using a first photolithographic layer comprising a first material, and the plurality of pivots is manufactured using a second photolithographic layer comprising a second material.

12. The probe card of claim 11 wherein the first material has a different Young's Modulus than the second material.

13. The probe card of claim 8, wherein the bending element is comprised of a nickel alloy.

14. The probe card of claim 8 wherein the probe further comprises a probe post connected to the probe tip, wherein the surface of the probe post is manufactured such that the probe post can be optically distinguished from the probe tip.
